(19) United States
(12) Patent Application Publication
(10) Pub. No.: US 2009/0205270 A1
(43) Pub. Date: Aug. 20, 2009

(54) Structured Photovoltaic Roofing Elements, Systems and Kits

(76) Inventors: Wayne E. Shaw, Glen Mills, PA (US); Gregory F. Jacobs, Oreland, PA (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/389,321

(22) Filed: Feb. 19, 2009

Related U.S. Application Data
(60) Provisional application No. 61/029,836, filed on Feb. 19, 2008.

(51) Int. Cl. E04D 13/18; H01L 31/048

(52) U.S. Cl. 52/173.3; 136/251

(57) ABSTRACT

The present invention relates generally to the photovoltaic generation of electrical energy. The present invention relates more particularly to photovoltaic roofing elements having a structured profile. For example, one aspect of the invention is a structured photovoltaic roofing element including: a structured roofing substrate presenting on its top-facing surface a plurality of differently-shadowable zones; and a plurality of bypassable photovoltaic elements, each of the bypassable photovoltaic elements comprising a bypass diode connected in parallel with a photovoltaic element, each of the bypassable photovoltaic elements being disposed in a differently-shadowable zone; wherein one or more of the bypassable photovoltaic elements is disposed in a different differently-shadowable zone than one or more of the other bypassable photovoltaic elements.

### CROSS-REFERENCE TO RELATED APPLICATIONS

This application claims priority under 35 U.S.C. § 119(e) to U.S. Provisional Patent Application Ser. No. 61/029,836, filed Feb. 19, 2008, which is hereby incorporated herein by reference in its entirety.

### BACKGROUND OF THE INVENTION

1. Field of the Invention

The present invention relates generally to the photovoltaic generation of electrical energy. The present invention relates more particularly to photovoltaic arrays, systems and roofing products in which a plurality of photovoltaic elements are electrically interconnected.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as system performance has improved. They can be used to provide at least a significant fraction of the electrical energy needed for a building's overall function; or they can be used to power one or more particular devices, such as exterior lighting systems and well pumps.

Aesthetically integrating photovoltaic media with a roof surface can be challenging. Acceptable aesthetics can be especially necessary for photovoltaic systems that are to be installed on a residential roof, as residential roofs tend to have relatively high slopes (e.g., > 4/12) and are therefore visible from ground level, and homeowners tend to be relatively sensitive to the aesthetic appearance of their homes. Roofing media such as tiles or panels having structured (i.e., not substantially flat) surfaces can provide a desirable visual appearance and aesthetically desirable architectural features.

While such structured roofing media are aesthetically beneficial, it can be difficult to integrate photovoltaic media with them. As the sun traverses the sky, a structured roofing product will have zones that are shadowed differently over the course of the day. Shadowed zones can make photovoltaic power generation markedly less efficient. First, any photovoltaic element disposed in the shadowed area generates less power. Moreover, and perhaps more importantly, the resistance of that shadowed photovoltaic element rises dramatically, which can make an entire series-connected array of photovoltaic elements (both those in shadow and those in sunlight) much less efficient at photovoltaic energy collection.

There remains a need for structured photovoltaic roofing elements, arrays and systems that address these deficiencies.

### SUMMARY OF THE INVENTION

One aspect of the present invention is a structured photovoltaic roofing element including:
a structured roofing substrate presenting on its top-facing surface a plurality of differently-shadowable zones; and
a plurality of bypassable photovoltaic elements, each of the bypassable photovoltaic elements comprising a bypass diode connected in parallel with a photovoltaic element, each of the bypassable photovoltaic elements being disposed in a differently-shadowable zone;
wherein one or more of the bypassable photovoltaic elements is disposed in a different differently-shadowable zone than one or more of the other bypassable photovoltaic elements.

Another aspect of the invention is a structured photovoltaic roofing element including:
a structured roofing substrate presenting on its top-facing surface a plurality of zones of a first shadowability and a plurality of zones of a second shadowability;
a first plurality of photovoltaic elements, each of the photovoltaic elements disposed in one of the zones of first shadowability, the first plurality of photovoltaic elements being connected in series, the series-connected first plurality being connected in parallel with a first bypass diode; and
a second plurality of photovoltaic elements, each of the photovoltaic elements disposed in one of the zones of second shadowability, the second plurality of photovoltaic elements being connected in series, the series-connected second plurality being connected in parallel with a second bypass diode;
wherein the zones of the first shadowability are differently-shadowable than the zones of the second shadowability.

Another aspect of the invention is a method for providing a structured photovoltaic roofing element, the method including
providing a structured roofing substrate presenting on its top-facing surface a plurality of differently shadowable zones; and
disposing a plurality of bypassable photovoltaic elements among the differently shadowable zones, so that one or more of the bypassable photovoltaic elements is disposed in a different differently-shadowable zone than one or more of the other bypassable photovoltaic element.

Another aspect of the invention is a structured photovoltaic roofing system including a plurality of structured photovoltaic roofing elements as described above, electrically interconnected.

The structured photovoltaic roofing elements, methods, systems and kits of the present invention can result in a number of advantages. For example, the structured photovoltaic roofing elements of the present invention can operate at a relatively high efficiency even as parts of them become shadowed. The structured photovoltaic roofing elements of the present invention can also provide a wide variety of aesthetically-desirable features to a rooftop. Other advantages will be apparent to the person of skill in the art.

The accompanying drawings are not necessarily to scale, and sizes of various elements can be distorted for clarity.

### BRIEF DESCRIPTION OF THE DRAWINGS

FIG. 1 is a diagram showing the azimuth and altitude of the sun over the course of a day;

FIG. 2 is a diagram showing the effect of tilt angle on the solar energy collection of a surface;

FIG. 3 is a diagram illustrating some of the parameters that are often taken into account in the placement of a photovoltaic array for optimal solar efficiency;

FIG. 4 is a schematic top perspective view and a schematic cross-sectional view of a structured photovoltaic roofing element;

FIG. 5 is a schematic exploded view of a photovoltaic element suitable for use in the present invention;

FIG. 6 is diagram illustrating schematic cross-sectional shapes of structured roofing substrates suitable for use in the present invention;

FIG. 7 is a schematic top perspective view of a house equipped with a photovoltaic roofing system;

FIG. 8 is a schematic edge view of a structured roofing substrate illuminated by sunlight with the sun high in the sky;

FIG. 9 is a schematic edge view of a structured roofing substrate illuminated by sunlight with the sun low in the eastern sky;

FIG. 10 is a schematic edge view of a structured roofing substrate illuminated by sunlight with the sun low in the western sky;

FIG. 11 is a schematic cross-sectional view of a section of an embodiment of a structured photovoltaic roofing element according to the present invention illuminated by sunlight with the sun low in the eastern sky;

FIG. 12 is a schematic cross-sectional view of the structured photovoltaic roofing element of FIG. 1 illuminated by sunlight with the sun high in the sky;

FIG. 13 is a schematic cross-sectional view of the structured photovoltaic roofing element of FIG. 1 illuminated by sunlight with the sun low in the western sky;

FIG. 14 is a schematic cross-sectional view of a section of a structured photovoltaic roofing element, illuminated by sunlight with the sun low in the sky;

FIG. 15 is a schematic perspective view of a structured photovoltaic roofing element according to one embodiment of the invention;

FIG. 16 is a schematic cross-sectional view and an electrical schematic view of structured photovoltaic element;

FIG. 17 is a top perspective view, a schematic cross-sectional view, and a top plan view of Comparative Example A; and

FIG. 18 is a schematic cross-sectional view, and a top plan view of Comparative Example B; and

FIG. 19 depicts a schematic cross-sectional view, and a top plan view of Example 1.

### DETAILED DESCRIPTION OF THE INVENTION

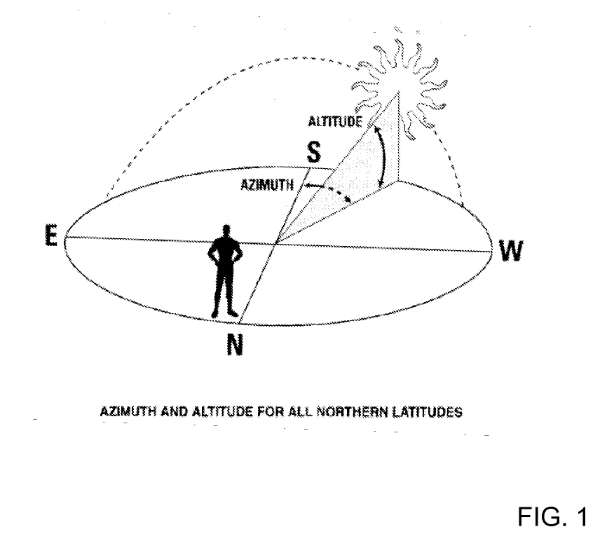

FIG. 1 is a diagram showing the azimuth and altitude of the sun over the course of a day relative to a location in the northern hemisphere. “Altitude” is the sun's height above the horizon, and is measured in degrees above the horizon. When the sun appears to be just rising or just setting, its altitude is 0 degrees. “Azimuth” is a measure of the east-west position of the sun and in the northern hemisphere is measured in degrees with respect to true south. When the sun is true south in the sky at 0 degrees azimuth, it will be at its highest altitude for that day. This time is called solar noon. A location's latitude determines how high the sun appears above the horizon at solar noon. The altitude of the sun at solar noon varies through the year.

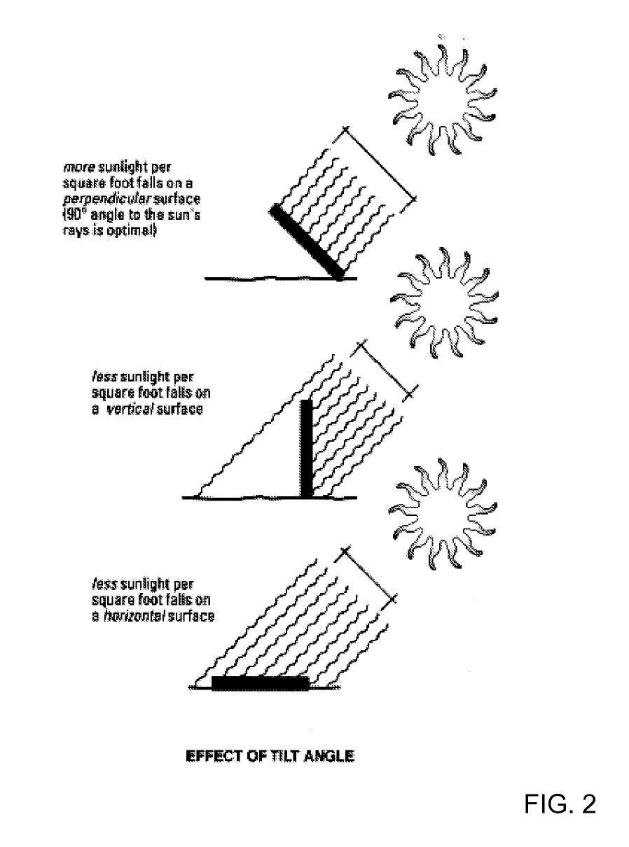

FIG. 2 is a diagram showing the effect of tilt angle on the solar energy collection of a surface. The highest amount of solar energy will fall on a surface when it is oriented in a plane perpendicular to the direction of the sun. Such a surface oriented to receive the most sunlight on average over the course of a year has its tilt angle roughly equal to the latitude of the location (e.g., 39° 57′ at Philadelphia, Pa., and 25° 46′ at Miami, Fla.). When the surface is that of a photovoltaic array, the efficiency of energy generation will be at its theoretical maximum when the array is normal to the sun, i.e., directly facing the sun in both azimuth and altitude. In the northern hemisphere, the tilt of the surface should be in a southerly direction; in the southern hemisphere, the tilt of the surface should be in a northerly direction.

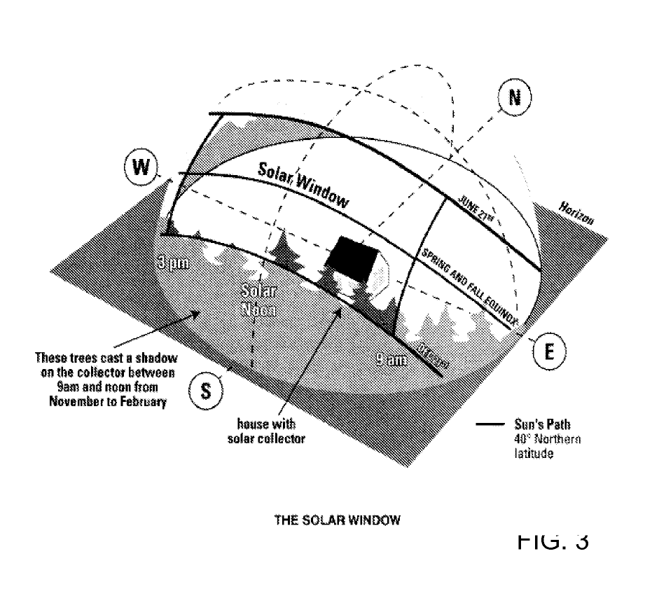

FIG. 3 is a diagram illustrating some of the parameters that are often taken into account in the placement of a photovoltaic array for optimal solar efficiency. A house with a solar collector is shown in relation to shadowing from nearby trees and landscape along with an indication of the path of the sun across the sky at various times through the year. Shading can affect the performance of a photovoltaic element. Unwanted shading of a photovoltaic system can occur from a variety of sources including trees, vegetation, other structures, poles, and overhead power lines. In the case of a photovoltaic roofing system based on structured photovoltaic roofing elements, the vertical structure of the roofing elements themselves can lead to shading effects.

One embodiment of a structured photovoltaic roofing element is shown in schematic top perspective view in FIG. 4. Structured photovoltaic roofing element 400 includes a structured roofing substrate 410. As used herein, a “structured roofing substrate” is a roofing substrate (e.g., in tile, panel or shingle form) that has a top surface that is not substantially flat. Structured roofing substrate 410 has a plurality of differently-shadowable zones; zones 412 would be cast into at least partial shadow when illumination is from the right; and zones 414 would be cast into at least partial shadow when illumination is from the left. Disposed on the structured roofing substrate are a plurality of bypassable photovoltaic elements 422 and 424. Each bypassable photovoltaic element includes a bypass diode connected in parallel with a photovoltaic element; when the resistivity of the photovoltaic element rises to an unacceptable level (e.g., due to shadowing), the bypass diode allows an alternate path for current flow, thus bypassing the photovoltaic element and allowing other (e.g., non-shadowed) photovoltaic elements to operate at acceptable efficiency. Each of the bypassable photovoltaic elements is disposed in a differently-shadowable zone; and one or more of the bypassable photovoltaic elements is disposed in a different differently-shadowable zone than one or more of the other bypassable photovoltaic elements. For example, in the embodiment of FIG. 4, bypassable photovoltaic elements 422 are disposed in the left-facing differently-shadowable zones 412; and bypassable photovoltaic elements 424 are disposed in the right-facing differently-shadowable zones 414.

The person of skill in the art will select bypass diode characteristics depending on a number of factors. The characteristics of the diode will depend, for example, on the type and size of photovoltaic element used, the intensity and variability of sunlight expected at the installation location, and the resistance at which a shaded photovoltaic element causes unacceptable system inefficiency. For example, the bypass diode can be configured to bypass a photovoltaic element when its output drops below about 30% of its maximum (i.e., in full sunlight at noon on the solstice) output (i.e., a about 30% or greater degradation in photovoltaically-generated current), below about 50% of its maximum output, below about 70% of its maximum output, below about 90% of its maximum output, or even below about 95% of its maximum output. For example, in one embodiment, in a 20 cell series-connected array of 1 volt/5 amp producing photovoltaic elements, the bypass diodes can be selected to bypass the photovoltaic elements when the output current drops below 4.75 amps (i.e., below 95% of the maximum output). Of course, as the person of skill will appreciate, each system design will have its own set of parameters; with higher amperage systems, relatively more degradation of current can be tolerated. In certain embodiments, the bypass diode can be an 8 amp bypass diode, available from Northern Arizona Wind & Sun, Flagstaff, Ariz.

In other embodiments, the bypass diode can be configured to bypass a photovoltaic element when its resistivity increases by at least about 400% of its resistivity at maximum output, at least about 300% of its resistivity at maximum output, at least about 100% of its resistivity at maximum output, at least about 50% of its resistivity at maximum output, at least about 25% of its resistivity at its maximum output, or even at least about 5% of its resisitivity at maximum output.

The differently-shadowable zones can be differently shadowable from one another, for example, because they have different angular orientations, and/or because they have different spatial orientations with respect to shadow-casting structures (e.g., peaks, protrusions) of the structured roofing substrate. Differently-shadowable zones can also be differently shadowable from one another because they have different spatial orientations with respect to shadow-casting structures external to the structured photovoltaic roofing element (e.g., trees, landscape, buildings). As a differently shadowable zone falls into partial or complete shadow (e.g., a shadow caused by another part of the structured photovoltaic roofing element itself) a photovoltaic element disposed on that zone would suffer a drop in current. This drop in current could negatively impact the performance of the entire photovoltaic system. The use of the bypassable photovoltaic element in that zone ameliorates this situation; as the shadowing causes the current to drop below a threshold level, the bypass diode effectively cuts that photovoltaic element out of the circuit, allowing the remainder of the array to function without a substantial loss of power.

Photovoltaic elements suitable for use in the various aspects of the present invention include one or more interconnected photovoltaic cells provided together, for example, in a single package. The photovoltaic cells of the photovoltaic elements can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide and copper indium gallium selenide. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of photovoltaic elements for use in the present invention. In one embodiment of the invention, the photovoltaic element includes a monocrystalline silicon photovoltaic cell or a polycrystalline silicon photovoltaic cell. The photovoltaic elements for use in the present invention can be flexible, or alternatively can be rigid.

The photovoltaic elements can be encapsulated photovoltaic elements, in which photovoltaic cells are encapsulated between various layers of material. For example, an encapsulated photovoltaic element can include a top layer material at its top surface, and a bottom layer material at its bottom surface. The top layer material can, for example, provide environmental protection to the underlying photovoltaic cells, and any other underlying layers. Examples of suitable materials for the top layer material include fluoropolymers, for example ETFE (“TEFZEL”, or NORTON ETFE), PFE, FEP, PVF (“TEDLAR”), PCTFE or PVDF. The top layer material can alternatively be, for example, a glass sheet, or a non-fluorinated polymeric material (e.g., polypropylene). The bottom layer material can be, for example, a fluoropolymer, for example ETFE (“TEFZEL”, or NORTON ETFE), PFE, FEP, PVDF or PVF (“TEDLAR”). The bottom layer material can alternatively be, for example, a polymeric material (e.g., polyolefin such as polypropylene, polyester such as PET); or a metallic material (e.g., steel or aluminum sheet).

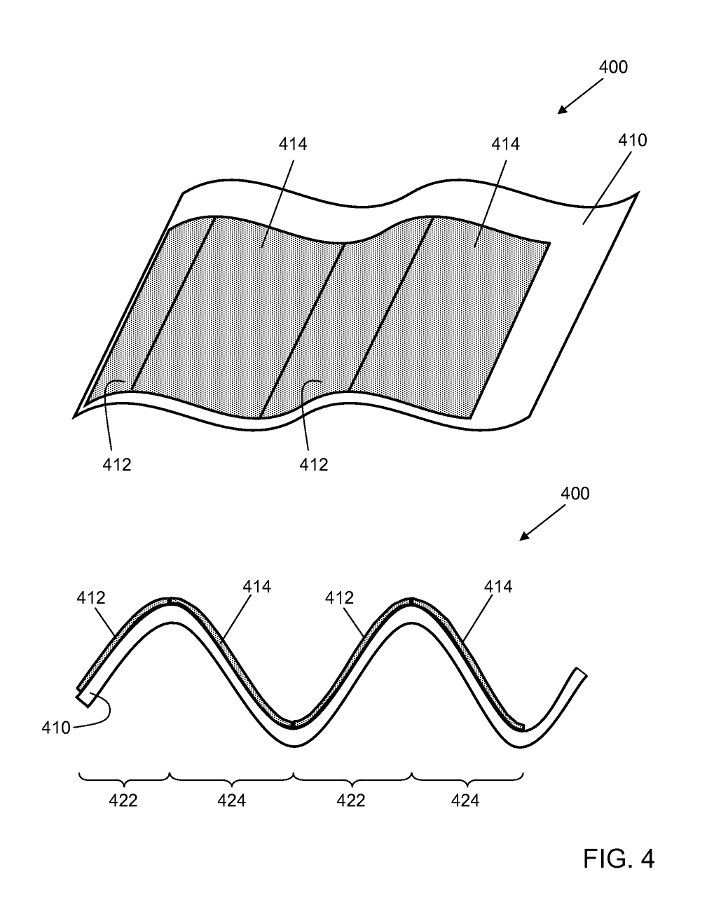

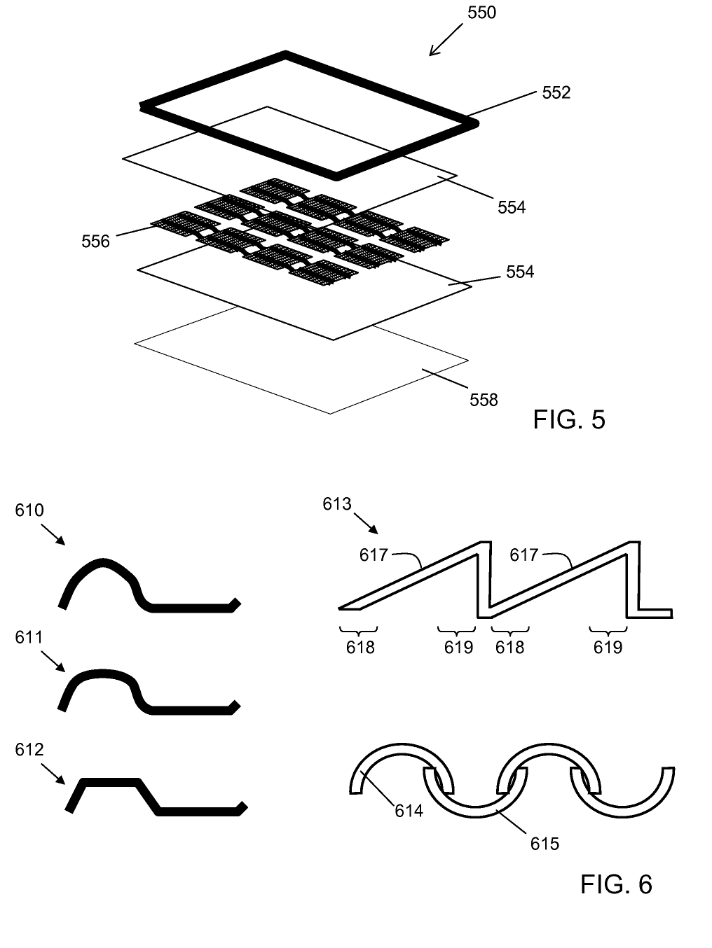

As the person of skill in the art will appreciate, an encapsulated photovoltaic element can include other layers interspersed between the top layer material and the bottom layer material. For example, an encapsulated photovoltaic element can include structural elements (e.g., a reinforcing layer of glass, metal, glass or polymer fibers, or a rigid film); adhesive layers (e.g., EVA to adhere other layers together); mounting structures (e.g., clips, holes, or tabs); one or more electrical connectors (e.g., electrodes, electrical connectors; optionally connectorized electrical wires or cables) for electrically interconnecting the photovoltaic cell(s) of the encapsulated photovoltaic element with an electrical system. An example of an encapsulated photovoltaic element suitable for use in the present invention is shown in schematic exploded view FIG. 5. Encapsulated photovoltaic element 550 includes a top protective layer 552 (e.g., glass or a fluoropolymer film such as ETFE, PVDF, PVF, FEP, PFA or PCTFE); encapsulant layers 554 (e.g., EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells 556; and a backing layer 558 (e.g., PVDF, PVF, PET).

The photovoltaic element can include at least one antireflection coating, for example as the top layer material in an encapsulated photovoltaic element, or disposed between the top layer material and the photovoltaic cells. The photovoltaic element can also be made colored, textured, or patterned, for example by using colored, textured or patterned layers in the construction of the photovoltaic element. Methods for adjusting the appearance of photovoltaic elements are described, for example, in U.S. Provisional Patent Applications Ser. No. 61/019,740, and U.S. patent application Ser. Nos. 11/456,200, 11/742,909, 12/145,166, 12/266,481 and 12/267,458 each of which is hereby incorporated herein by reference.

Suitable photovoltaic elements can be obtained, for example, from China Electric Equipment Group of Nanjing, China, as well as from several domestic suppliers such as Uni-Solar Ovonic, Sharp, Shell Solar, BP Solar, USFC, FirstSolar, General Electric, Schott Solar, Evergreen Solar and Global Solar. Moreover, the person of skill in the art can fabricate encapsulated photovoltaic elements using techniques such as lamination or autoclave processes. Encapsulated photovoltaic elements can be made, for example, using methods disclosed in U.S. Pat. No. 5,273,608, which is hereby incorporated herein by reference. Flexible photovoltaic elements are commercially available from Uni-Solar as L-cells having a dimension of approximately 9.5″×14″, S-cells having dimensions of approximately 4.75″×14″, and T-cells having dimensions of approximately 4.75″×7″. Photovoltaic elements of custom sizes can also be made.

The photovoltaic element also has an operating wavelength range. Solar radiation includes light of wavelengths spanning the near UV, the visible, and the near infrared spectra. As used herein, the term “solar radiation,” when used without further elaboration means radiation in the wavelength range of 300 nm to 2500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the photovoltaic element falls within the range of about 300 nm to about 1200 nm.

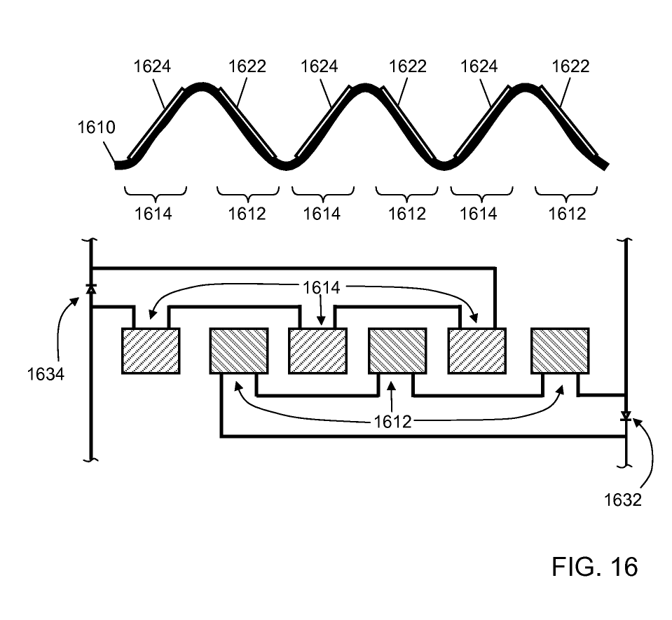

As described above, the photovoltaic elements are electrically interconnected with a bypass diode to form bypassable photovoltaic elements. Each photovoltaic element can be interconnected in parallel with its own bypass diode to form a bypassable photovoltaic element. In certain embodiments, a plurality of photovoltaic elements are connected in series, and the series-connected string of photovoltaic elements is connected in parallel with a single bypass diode to form a plurality of bypassable photovoltaic elements (e.g., as described below with respect to FIG. 16). The bypass diode can be provided in the same encapsulated package as the photovoltaic element, or alternatively can be wired separately (e.g., as part of a wiring system that interconnects the photovoltaic elements). Moreover, a plurality of the bypassable photovoltaic elements can be integrated together in a single package (e.g., connected in series and encapsulated between layers of polymer films), and disposed together on the structured roofing substrate. In certain embodiments, a plurality of bypassable photovoltaic elements are provided in strip form, and arranged in parallel integrated together in a single package, for example as shown in FIG. 19. Moreover, a plurality of bypassable photovoltaic elements can be formed on a single substrate as a plurality of individual photovoltaic cells, each with its own bypass diode, for example as shown in U.S. Pat. No. 6,690,041, which is hereby incorporated by reference in its entirety.

The present invention can be practiced using any of a number of types of structured roofing substrates. For example, in one embodiment, the structured roofing substrate is a rigid structured roofing substrate. In certain embodiments, such a rigid structured roofing substrate can take the form of a roofing tile (e.g., a barrel tile), shake or shingle. In other embodiments, a rigid structured roofing substrate can take the form of a roofing panel. In certain embodiments of the invention, the rigid structured roofing substrate is formed from a polymeric material. Suitable polymers include, for example, polyolefin, polyethylene, polypropylene, ABS, PVC, polycarbonates, nylons, EPDM, TPO, fluoropolymers, silicone, rubbers, thermoplastic elastomers, polyesters, PBT, poly(meth)acrylates, epoxies, and can be filled or unfilled or formed. The rigid structured roofing substrate can be, for example, a polymeric tile, shake or shingle. The rigid structured roofing substrate can be made of other materials, such as metallic, composite, clay or ceramic, or cementitious materials. In other embodiments, the structured roofing substrate is a flexible roofing substrate, for example a bituminous shingle or a roofing membrane. Such a roofing substrate can be provided as substantially flat, but be installed on a structured surface (e.g., a structured roof deck), taking its shape when installed. The manufacture of photovoltaic roofing elements using a variety of roofing substrates are described, for example, in U.S. patent application Ser. Nos. 12/146,986, 12/266,409, 12/268,313, 12/351,653, and 12/339,943, and U.S. Patent Application Publication no. 2007/0266562, each of which is hereby incorporated herein by reference in its entirety.

The structured roofing substrate can have a variety of configurations. For example, in certain embodiments of the invention, the structured photovoltaic roofing element has a wavy configuration. For example, in one embodiment, the structured roofing substrate can be a wavy roofing tile. Bypassable photovoltaic elements are disposed on the tile on different faces of its waveform-like shape (e.g., as described above with reference to FIG. 4). For example, a single wave can be associated with two differently shadowable zones, one on the face to the right of its peak, and one on the face to the left of its peak. These faces have different angular orientations, and will be shadowed by the peaks of the wave shape at different times of day (e.g., one in the morning, and the other in the evening). One bypassable photovoltaic element can be disposed on the face to the right of a peak of a wave, and another bypassable photovoltaic element can be disposed on the face to the left of the peak. If the left-facing bypassable photovoltaic element is shaded, its bypass diode will cut that photovoltaic element out of the circuit, thereby causing a minimal impact on the performance of the right-facing bypassable photovoltaic element. Conversely, if the right-facing bypassable photovoltaic element is shaded, its bypass diode will cut that photovoltaic element out of the circuit, thereby causing a minimal impact on the performance of the left-facing bypassable photovoltaic element.

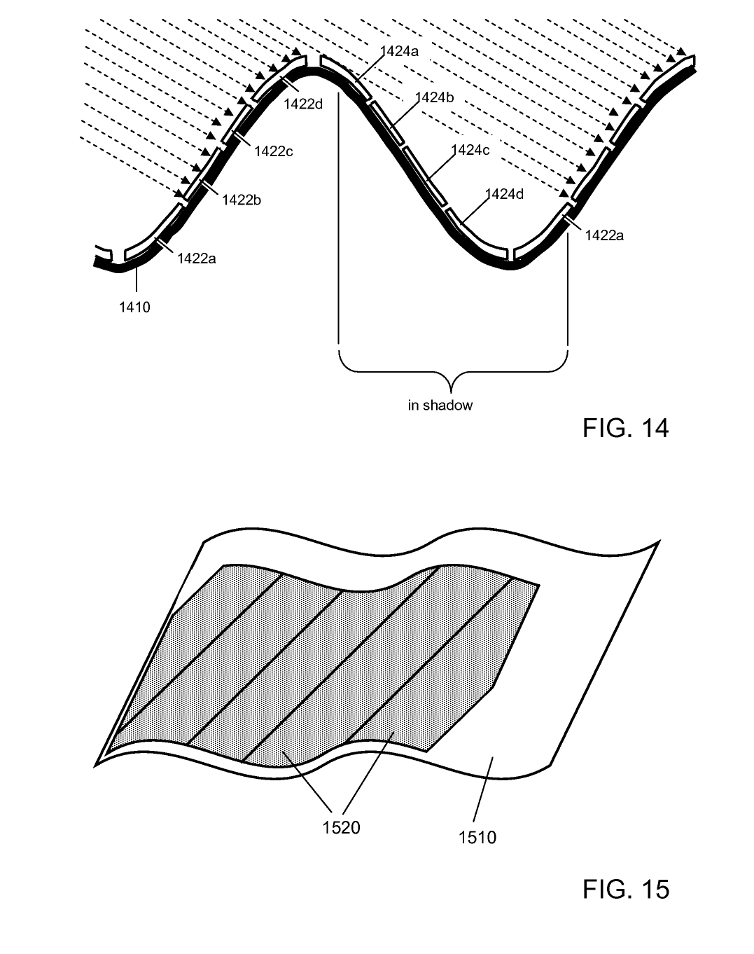

In one embodiment of the invention, the structured roofing substrate has a plurality of faces, each of the faces including a single differently shadowable zone, and having a single bypassable photovoltaic element disposed thereon. However, in other embodiments of the invention, each of the faces of the structured roofing substrate including a plurality of differently-shadowable zones and has disposed thereon a plurality of bypassable photovoltaic elements (e.g., as described below with reference to FIG. 14). As a shadow traverses the face, each of the bypassable photovoltaic elements can remain in full sunlight, and therefore retain activity for a maximum amount of time.

FIG. 6 shows a variety of additional schematic cross-sectional shapes of structured roofing substrates 610-615 suitable for use in the present invention. Each of these shapes has surfaces that when installed on a roof would present themselves at different angles to solar radiation. One embodiment of a structured roofing substrate useable in the present invention is shown at reference numeral 613 at the top right of FIG. 6. In use, each diagonal surface 617 of the sawtooth could have a number of differently shadowable zones. A zone 618 toward the bottom of the diagonal surface would be the first to be shaded as an illumination source moves from center to left, while zones toward the peak of the sawtooth would be the last to fall into shadow. In this embodiment of the invention, the differently shadowable zones all have the same angular orientation, but are differently shadowable due to their differing spatial orientations with respect to the shadow-casting structures (i.e., the peak of the adjacent sawtooth).

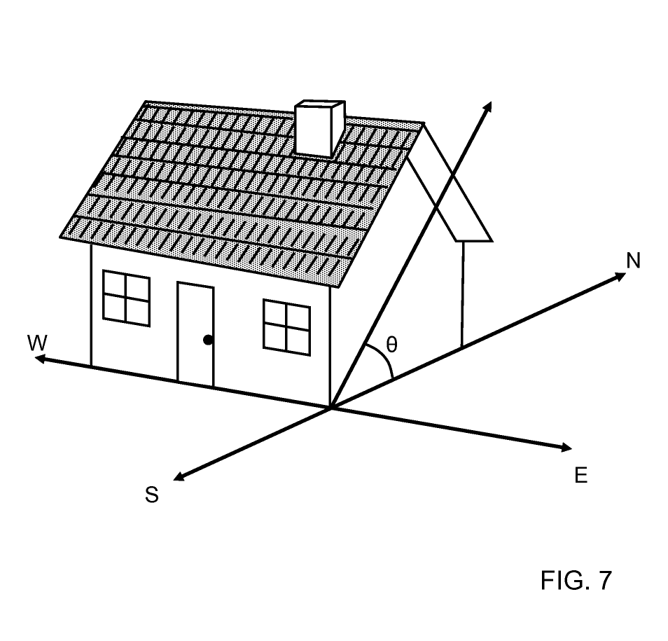

FIG. 7 shows a schematic top perspective view of a house equipped with a photovoltaic roofing system. The house is oriented with photovoltaic roofing system on a south-facing portion of the roof and the slope of the roof is inclined to an angle (θ) matching the latitude of the location of the house. This is a theoretically optimal roof orientation for the capture of incident solar energy. Of course, in real-world situations, other factors will often dictate the orientation of the roof surface(s). As the orientation departs from true south, not only will the overall average solar illumination decrease, but also shadowing problems will increase. In some embodiments, the photovoltaic product is oriented so that when the sun is highest in the sky, the general plane of the roof will be close to normal to the incident sunlight.

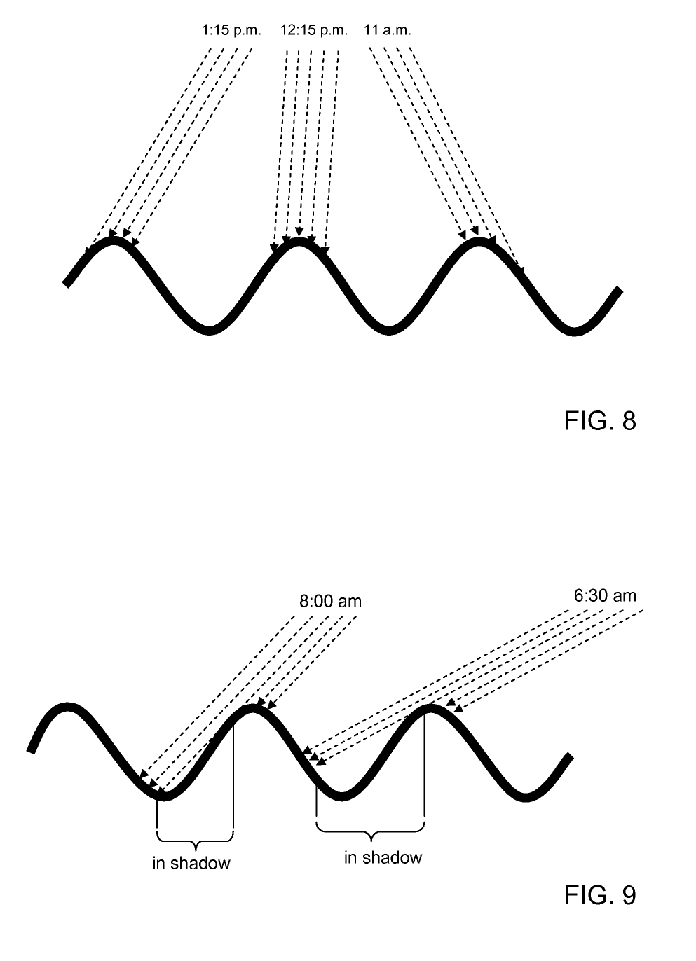

FIG. 8 is a schematic edge view of a structured (in this example, wavy) roofing substrate illuminated by sunlight with the sun high in the sky (e.g., close to solar noon—at 11 am, 12:10 pm, and 1:15 pm). In FIG. 8, shadows are not cast on any portion of the structured photovoltaic roofing element, and therefore any photovoltaic elements disposed thereon can be fully illuminated by sunlight. While FIG. 8 (as well as FIGS. 9-14 below) depicts illumination from a specific angle, there may be occasions where diffuse illumination (e.g., from a cloudy sky) can contribute to activation of the photovoltaic elements.

FIG. 9 is a schematic edge view of a structured roofing substrate with a generally south-facing overall orientation illuminated by sunlight with the sun low in the eastern sky. Two times are shown (e.g., 6:30 am and 8:00 am). Shadows are cast on portions of the structured roofing substrate that are occluded from the sun by its vertically-extending structure. Any bypassable photovoltaic elements disposed (in whole or in part) in the shadowed zones are susceptible to suffering a drop in power generation, and therefore a concomitant increase in resistivity, thereby negatively impacting the efficiency of the entire photovoltaic roofing system. If the resistivity of the photovoltaic element rises to an unacceptable level, the bypass diode will be activated, and provide an alternative path for current flow, bypassing the highly resistive photovoltaic element.

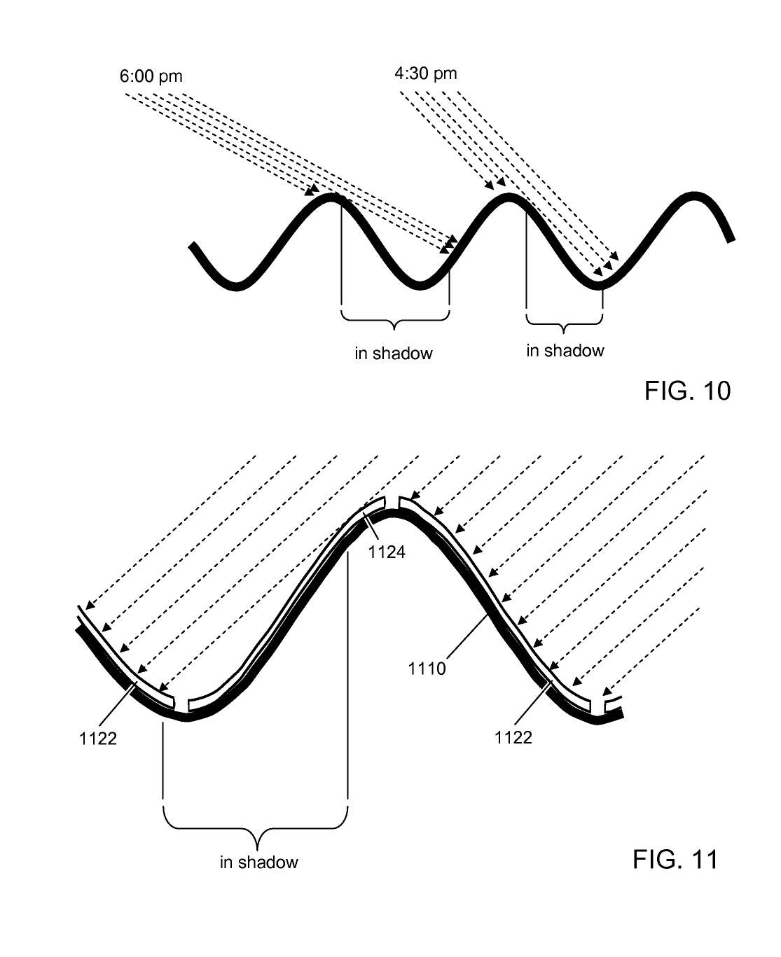

Similarly, FIG. 10 is a schematic edge view of a generally south-facing structured roofing substrate illuminated by sunlight with the sun low in the western sky. Two times are shown (e.g., 4:30 pm and 6:00 pm). As described above, shadows are cast on portions of the structured roofing product that are occluded from the sun by the structure of the structured photovoltaic roofing element; the bypass diodes of the bypassable photovoltaic elements disposed thereon can allow any insufficiently illuminated photovoltaic elements to be temporarily removed from the circuit so that they do not drag down the performance of the rest of the system.

FIG. 11 is a schematic cross-sectional view of a section of an embodiment of a structured photovoltaic roofing element according to the present invention, installed in a generally south-facing direction. In this embodiment, the borders between adjacent bypassable photovoltaic elements 1122 and 1124 are at the peaks and valleys of the structured roofing substrate 1110. In the embodiment of FIG. 11, most of the left-facing bypassable photovoltaic element 1124 is in shadow due to the relatively low angle of incident sunlight (e.g., early morning illumination). The bypass diodes of the bypassable photovoltaic elements allow current to flow past the photovoltaic elements that are not sufficiently illuminated (in this example, the left-facing element), thus reducing the effect of shadowing as compared to a structured PV roofing system not so equipped.

FIG. 12 shows the structured photovoltaic roofing element of FIG. 11 illuminated by sunlight with the sun high in the sky (e.g., at solar noon). Shadows are not cast on any portions of the structured photovoltaic roofing element, and both the left-facing and the right-facing bypassable photovoltaic elements 1124 and 1122 are substantially illuminated.

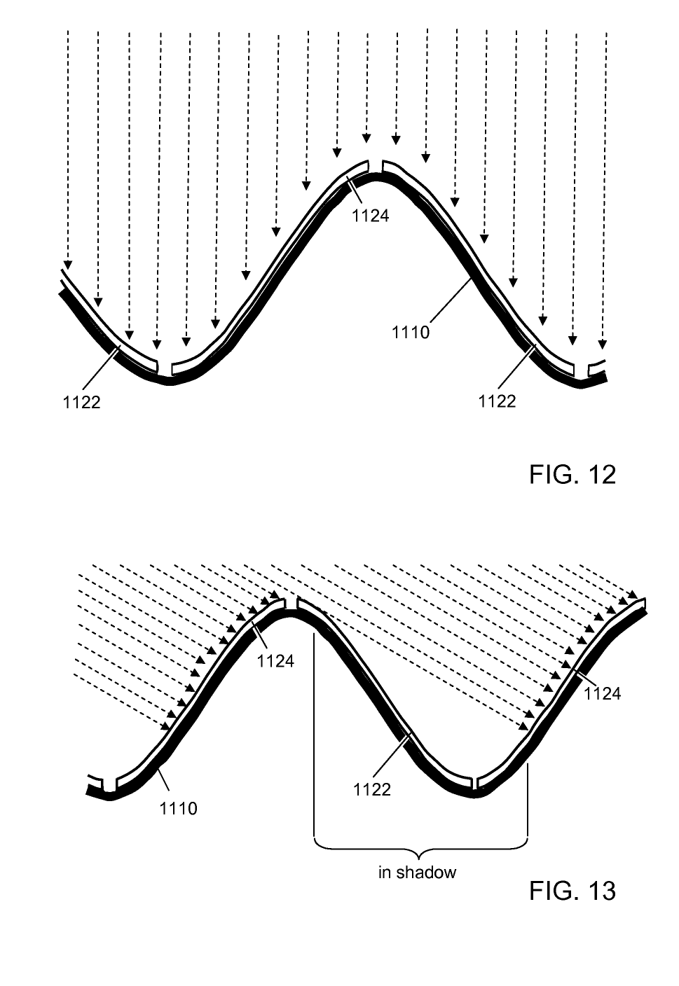

FIG. 13 shows the structured photovoltaic roofing element of FIG. 11 (in a slightly different sectional view) illuminated by sunlight with the sun low in the western sky (e.g., late afternoon). In FIG. 13, the right-facing bypassable photovoltaic element 1122 is in shadow, and can be cut out of the circuit by its bypass diode. In fact, part of the left-facing bypassable photovoltaic elements 1124 are also in shadow, but not enough to severely impact performance and cause current to flow through their bypass diodes. As described above, the person of skill in the art can select the bypass diode so that it becomes active at a desired resistivity of its corresponding photovoltaic element.

FIG. 14 is a schematic cross-sectional view of a section of another embodiment of a structured photovoltaic roofing element, illuminated by sunlight with the sun low in the sky. In this embodiment, each face of the structured roofing substrate 1410 has four bypassable photovoltaic elements (1422a-d on the right-facing faces; and 1424a-d on the left-facing faces), with borders between them not only at peaks and valleys but also in the within the left- and right-facing faces themselves. The bypass diodes of the bypassable photovoltaic elements allow current to flow past any photovoltaic elements that are not sufficiently illuminated, thus reducing the effect of shadowing as compared to a structured photovoltaic roofing element not so equipped. As compared with FIG. 13, more of the individual bypassable photovoltaic elements are at full illumination (e.g., not partially or completely in shadow). As the sun moves to lower angles and shadows move across the structured photovoltaic roofing element, more of the individual bypassable photovoltaic elements can remain substantially illuminated for a longer time. Of course, other numbers of bypassable photovoltaic elements can be presented on each face of the structured photovoltaic roofing element.

In the embodiment of FIG. 4, the bypassable photovoltaic elements are shown as being aligned parallel to the lateral edge of the tile. Of course, other configurations are possible. For example, in certain configurations, shadows can be cast along a diagonal of each structured roofing element. Accordingly, in one embodiment of the invention, bypassable photovoltaic elements 1520 are distributed diagonally along the structured roofing substrate 1510, as shown in schematic perspective view in FIG. 15. When installed on a roof, the structured photovoltaic roofing elements according to this embodiment of the invention can be disposed so that the diagonal borders are substantially parallel to the shadow front (e.g., substantially parallel to the year-average shadow front angle). For example, diagonal configurations can be desirable for a roof that does not face true south; the angle of the diagonal can be chosen to correspond to the angle of the shadow front across the structured photovoltaic roofing element as the sun traverses the daytime sky. Structured photovoltaic roofing elements having different diagonal configurations can be used on separate roof sections having different shadowing characteristics.

It will be understood that other arrangements of bypassable photovoltaic elements may be used depending, for example, on the shape of the structured roofing substrate and the position of the roof section on which it is disposed. For example, the plurality of bypassable photovoltaic elements can be disposed on the structured roofing substrate not as parallel strips, but in some other configuration. Certain structured roofing substrates may have specific zones that are more prone to shadowing than the rest of the structured roofing substrate; such zones could be isolated through use of bypassable photovoltaic elements. In one embodiment, the plurality of bypassable photovoltaic elements can be disposed as a two-dimensional array or mosaic of series-connected elements. The person of skill in the art can use placement of the bypassable photovoltaic elements to control of shadowing effects to maximize the number of fully-illuminated photovoltaic elements over the course of the day.

The bypassable photovoltaic elements can be electrically interconnected in a variety of ways. For example, in one embodiment, the bypassable photovoltaic elements of a structured photovoltaic roofing element are electrically interconnected in series. In another embodiment, the bypassable photovoltaic elements of a structured photovoltaic roofing element are electrically interconnected in parallel-series, as described in U.S. patent application Ser. No. 12/359,978, which is hereby incorporated herein by reference in its entirety. In certain embodiments, the bypassable photovoltaic elements are connected in series-parallel.

One embodiment of a structured photovoltaic element according to this aspect of the invention is shown in schematic cross-sectional view and in electrical schematic view in FIG. 16. The structured roofing substrate 1610 has three zones of a first shadowability (the three left-facing zones 1614), upon which three left-facing photovoltaic elements 1624 are disposed. The structured roofing substrate 1610 also has three zones of a second shadowability (the three right-facing zones 1612), upon which three right-facing photovoltaic elements 1622 are disposed. The three left-facing photovoltaic elements 1624 are connected in series, then in parallel with a first bypass diode 1634. The three right-facing photovoltaic elements 1622 are connected in series, then in parallel with a second bypass diode 1632. In use, when the left-facing photovoltaic elements are in shadow, the first bypass diode can cut them out of the circuit together. Similarly, when the right facing photovoltaic elements are in shadow, the second bypass diode can cut them out of the circuit. Advantageously, this embodiment allows the construction of structured photovoltaic roofing elements using fewer bypass diodes by allowing photovoltaic elements in zones of substantially similar shadowability to be controlled by a single bypass diode. In the embodiment shown in FIG. 16, the left-facing set of photovoltaic elements 1624 and the right-facing set of photovoltaic elements 1622 can be individually electrically connected in a photovoltaic array. In another embodiment, the two series-parallel circuits are connected in series to provide a structured photovoltaic roofing element having a single pair of electrical leads.

Another aspect of the invention is a method of making a structured photovoltaic element. The method includes providing a structured roofing substrate presenting on its top-facing surface a plurality of differently shadowable zones. A plurality of bypassable photovoltaic elements are disposed among the differently shadowable zones and electrically interconnected (e.g., in series), so that one or more of the bypassable photovoltaic elements is disposed in a different differently-shadowable zone than one or more of the other bypassable photovoltaic element.

Another aspect of the invention is a photovoltaic roofing system including a plurality of structured photovoltaic roofing elements as described above, electrically interconnected. The photovoltaic roofing system can be interconnected with an inverter to allow photovoltaically-generated electrical power to be used on-site, stored in a battery, or introduced to an electrical grid.

Electrical interconnections can be made in a variety of ways in the structured photovoltaic roofing elements, methods and systems of the present invention. The bypassable photovoltaic elements can be provided with electrical connectors (e.g., available from Tyco International), which can be connected together to provide the desired interconnections. In other embodiments, the bypassable photovoltaic elements can be wired together using lengths of electrical cable. Electrical connections are desirably made using cables, connectors and methods that meet UNDERWRITERS LABORATORIES and NATIONAL ELECTRICAL CODE standards. Electrical connections are described in more detail, for example, in U.S. patent application Ser. Nos. 11/743,073 12/266,498, 12/268,313, 12/359,978 and U.S. Provisional Patent Application Ser. No. 61/121,130 each of which is incorporated herein by reference in its entirety. The wiring system can also include return path wiring (not shown), as described in U.S. Provisional Patent Application Ser. No. 61/040,376, which is hereby incorporated herein by reference in its entirety.

In certain embodiments of the invention a plurality of structured photovoltaic roofing elements are disposed on a roof deck and electrically interconnected. There can be one or more layers of material (e.g. underlayment), between the roof deck and the structured photovoltaic roofing elements. The structured photovoltaic roofing elements can be installed on top of an existing roof, in such embodiments, there would be one or more layers of standard (i.e., non-photovoltaic) roofing elements (e.g., asphalt coated shingles) between the roof deck and the structured photovoltaic roofing elements. Even when the structured photovoltaic roofing elements are not installed on top of preexisting roofing materials, the roof can also include one or more standard roofing elements, for example to provide weather protection at the edges of the roof, or in areas not suitable for photovoltaic power generation. In some embodiments, non-photovoltaically-active roofing elements are complementary in appearance or visual aesthetic to the structured photovoltaically roofing elements.

Another embodiment of the invention is a kit for the assembly of a photovoltaic roofing system. The kit includes a plurality of structured roofing substrates, each presenting on its top-facing surface a plurality of differently-shadowable zones, as described above, and a plurality of bypassable photovoltaic elements configured to be disposed upon the differently-shadowable zones. The kit may also include an electrical connection system sufficient to electrically interconnect the bypassable photovoltaic elements, for example as described above. The electrical connection system can be integral to the bypassable photovoltaic elements (e.g., as connectors and electrical cables attached to the photovoltaic elements) and/or the structured roofing substrates (e.g., as connectors and electrical cables attached to the structured roofing substrates); or can be provided as separate components.

### Comparative Example A

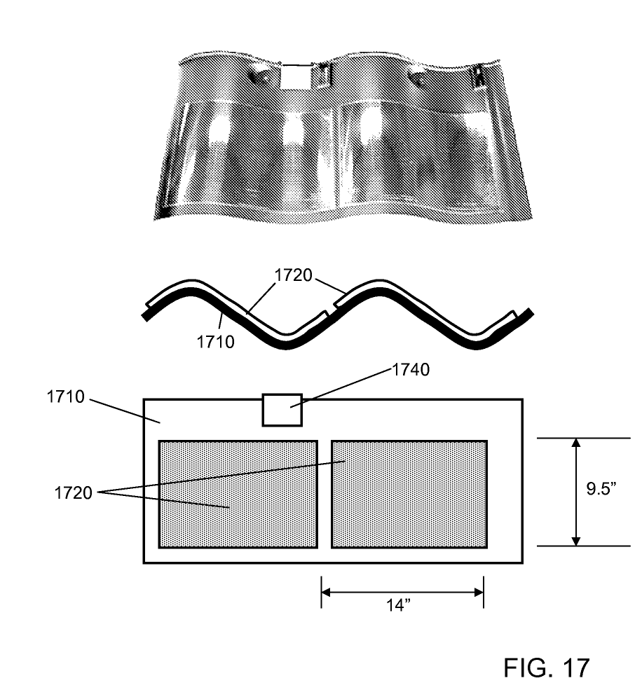

FIG. 17 presents a top perspective view, a schematic cross-sectional view, and a top plan view of Comparative Example A. A structured roofing substrate 1710 having a wavy tile structure (like the one depicted in FIG. 4) is made from a molded rigid plastic material, as described in more detail in U.S. Patent Application Publication no. 2008/0302408, which is hereby incorporated by reference in its entirety. Two flexible photovoltaic elements 1720 are attached to the upper surface of the substrate, and connected in series. The photovoltaic elements are L-Cells available from Uni-Solar Ovonic, Auburn Hills, Mich., and traverse a large portion of each period of the waveform shape of the structured roofing substrate. Notably, the two photovoltaic elements have substantially the same configuration with respect to peaks and valleys of the waveform, and therefore are substantially similarly shadowable. A connector 1740 is disposed on the structured roofing substrate is electrically connected to the series-connected photovoltaic elements. Under certain illumination conditions, such as, for example shown in FIGS. 9 and 10, portions of the photovoltaic elements are susceptible to shadowing by the peaks of the structured roofing substrate and can have diminished electrical output as a result.

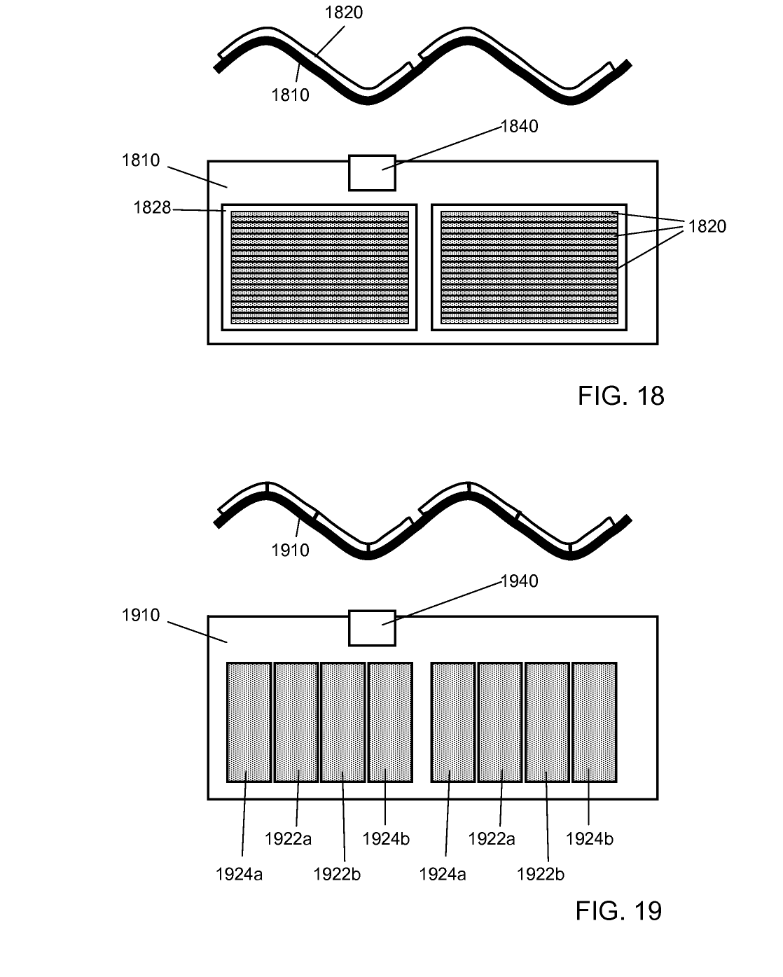

FIG. 18 presents a schematic cross-sectional view and a top plan view of Comparative Example B. A structured roofing substrate 1810 and a connector 1840 similar to the structured roofing substrate 1710 and connector 1740 of FIG. 17 is provided. In Comparative Example B, a plurality of bypassable photovoltaic elements 1820 are connected in series and packaged together in a single encapsulated package 1828. Notably, the bypassable photovoltaic elements 1820 are arranged in parallel strips. The encapsulated package 1828 is disposed on the top surface of structured roofing substrate 1810. The bypassable photovoltaic elements have substantially similar positioning with respect to the peaks and valleys of the structured roofing substrate 1810, and therefore are in zones of substantially similar shadowability.

### Example 1

FIG. 19 depicts a schematic cross-sectional view, and a top plan view of Example 1. In Example 1, a structured product substrate 1910 (having connector 1940) similar to that of Comparative Examples A and B is used, but with smaller bypassable photovoltaic elements 1922a, 1822b, 1824a, 1824b. The individual bypassable photovoltaic elements are connected in series. The bypassable photovoltaic elements have a width that is about one quarter of the wavelength of the waveform shape of the structured roofing substrate. In this embodiment, the bypassable photovoltaic elements 1922a, 1922b, 1924a, 1924b are in differently shadowable zones; 1922a and 1922b are right-facing, while 1924a and 1924b are left-facing, and 1922a and 1824a are disposed toward the top of a peak of the structured roofing substrate, while 1922b and 1924b are disposed toward the bottom of a valley of the structured roofing substrate.

Further, the foregoing description of embodiments of the present invention has been presented for the purposes of illustration and description. It is not intended to be exhaustive or to limit the invention to the precise forms disclosed. Many modifications and variations are possible in light of the above teaching. Further, the structured photovoltaic roofing elements of the present invention can be utilized with many different building structures, including residential, commercial and industrial building structures.

Chapters 3 and 5 from the PHOTOVOLTAICS: Design and Installation Manual (Solar Energy International, New Society Publishers, Gabriola Island, British Columbia, Canada, 2004 (ISBN 0-86571-520-3) are hereby incorporated herein by reference in their entirety.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

What is claimed is:

1. A structured photovoltaic roofing element comprising:
a structured roofing substrate presenting on its top-facing surface a plurality of differently-shadowable zones; and
a plurality of bypassable photovoltaic elements, each of the bypassable photovoltaic elements comprising a bypass diode connected in parallel with a photovoltaic element, each of the bypassable photovoltaic elements being disposed in a differently-shadowable zone;
wherein one or more of the bypassable photovoltaic elements is disposed in a different differently-shadowable zone than one or more of the other bypassable photovoltaic elements.

2. A structured photovoltaic roofing element according to claim 1, wherein the structured roofing substrate is a rigid roofing substrate.

3. A structured photovoltaic roofing element according to claim 2, wherein the structured roofing substrate is a tile, shake or shingle.

4. A structured photovoltaic roofing element according to claim 2, wherein the structured roofing substrate is a roofing panel.

5. A structured photovoltaic roofing element according to claim 1, wherein the structured roofing substrate is a flexible roofing substrate installed on a structured surface.

6. A photovoltaic roofing element according to claim 5, wherein the roofing substrate is a bituminous shingle or a roofing membrane.

7. A structured photovoltaic roofing element according to claim 1, wherein the differently-shadowable zones have different angular orientations.

8. A structured photovoltaic roofing element according to claim 1, wherein the structured roofing substrate comprises one or more shadow-casting structures, and wherein the differently-shadowable zones have different spatial orientations with respect to the one or more shadow-casting structures.

9. A structured photovoltaic roofing element according to claim 1, wherein the structured roofing substrate has a plurality of faces, each face comprising a single differently-shadowable zone and having a single bypassable photovoltaic element disposed thereon.

10. A structured photovoltaic roofing element according to claim 1, wherein the structured roofing substrate has a wavy configuration.

11. A structured photovoltaic roofing element according to claim 1, wherein the structured roofing substrate has a plurality of faces, each of the faces comprising a single differently shadowable zone, and having disposed thereon a single bypassable photovoltaic element.

12. A structured photovoltaic roofing element according to claim 1, wherein the structured roofing substrate has a plurality of faces, each of the faces comprising a plurality of differently-shadowable zones and having disposed thereon a plurality of bypassable photovoltaic elements.

13. A structured photovoltaic roofing element according to claim 1, wherein the plurality of bypassable photovoltaic elements are electrically interconnected in series.

14. A structured photovoltaic roofing element according to claim 1, wherein
the structured roofing substrate presents on its top-facing surface a plurality of zones of a first shadowability and a plurality of zones of a second shadowability, the zones of the first shadowability being differently-shadowable than the zones of the second shadowability; and
the plurality of bypassable photovoltaic elements comprises
a first plurality of photovoltaic elements, each of the photovoltaic elements disposed in one of the zones of first shadowability, the first plurality of photovoltaic elements being connected in series, the series-connected first plurality being connected in parallel with a first bypass diode; and
a second plurality of photovoltaic elements, each of the photovoltaic elements disposed in one of the zones of second shadowability, the second plurality of photovoltaic elements being connected in series, the series-connected second plurality being connected in parallel with a second bypass diode.

15. The structured photovoltaic roofing element according to claim 1, wherein in each bypassable photovoltaic element, the bypass diode is configured to bypass the photovoltaic element when its output drops below about 30% of its maximum output.

16. The structured photovoltaic roofing element according to claim 1, wherein in each bypassable photovoltaic element, the bypass diode is configured to bypass the photovoltaic element when its resistivity increases by at least about 100% of its resistivity at maximum output.

17. A method for providing a structured photovoltaic roofing element according to claim 1, the method comprising
providing a structured roofing substrate presenting on its top-facing surface a plurality of differently shadowable zones; and
disposing a plurality of bypassable photovoltaic elements among the differently shadowable zones, so that one or more of the bypassable photovoltaic elements is disposed in a different differently-shadowable zone than one or more of the other bypassable photovoltaic elements.

18. A structured photovoltaic roofing system comprising a plurality of structured photovoltaic roofing elements according to claim 1, electrically interconnected.

19. A kit for the assembly of a photovoltaic roofing system according to claim 18, the kit comprising
a plurality of structured roofing substrates, each presenting on its top-facing surface a plurality of differently-shadowable zones; and
a plurality of bypassable photovoltaic elements configured to be disposed upon the differently-shadowable zones.
